(19) United States
(12) Patent Application Publication
(10) Pub. No.: US 2022/0005896 A1
(43) Pub. Date: Jan. 6, 2022

(54) DISPLAY DEVICE

(71) Applicant: SHARP KABUSHIKI KAISHA, Sakai City, Osaka (JP)

(72) Inventors: KAORU ABE, Sakai City, Osaka (JP); TAKESHI YANEDA, Osaka City, Osaka (JP)

(21) Appl. No.: 17/280,837

(22) PCT Filed: Sep. 26, 2018
(86) PCT No.: PCT/JP2018/035802

§ 371 Date: Mar. 26, 2021

(51) Int. Cl. H01L 27/32

(52) U.S. Cl. CPC H01L 27/3248; H01L 27/3218; H01L 27/3276

(57) ABSTRACT

A first opening of an edge cover that exposes a first electrode formed in a surface display region is larger than a second opening of an edge cover that exposes a first electrode formed in a side display region, and a light-emitting layer that overlaps the first opening has equal shape and equal size to a light-emitting layer that overlaps the second opening.

### TECHNICAL FIELD

The present invention relates to a display device.

### BACKGROUND ART

In regard to a display device, PTLs 1 to 3 disclose a configuration in which a dummy region not being used for display is provided around a display region. Further, in recent years, a display device in which a display region is formed on a surface and a side surface has been put to practical use.

### CITATION LIST

### Patent Literature

PTL 1: JP 2015-158572 A
PTL 2: JP 2009-081097 A
PTL 3: JP 2007-11556 A

### SUMMARY OF INVENTION

### Technical Problem

In the display device as described above, a fine metal mask (FMM) is used when a luminescent material is deposited during manufacturing. In a case of the display device in which a display region is formed on a surface and a side surface, display in the side display region is required, but it is particularly difficult to maintain a mask precision at an end portion of the display region. Thus, there is a problem in that a yield becomes poor and a cost increases.

The present invention has been made to solve the above-described problem, and an object thereof is to improve a yield of a display device in which a display region is formed on a surface and a side surface.

### Solution to Problem

In order to solve the above-described problem, a display device according to an aspect of the present invention in which a plurality of light-emitting elements are formed, the plurality of light-emitting elements each including a first electrode, an edge cover formed in a layer above the first electrode and covering an end portion of the first electrode, a light-emitting layer formed in a layer above the first electrode, and a second electrode formed in a layer above the light-emitting layer is the display device including: a first display region provided on a surface of the display device, a plurality of first light-emitting elements being formed in the first display region; and a second display region continuous with the first display region and provided on a side surface of the display device, a plurality of second light-emitting elements being formed in the second display region, wherein a first opening of the edge cover that exposes the first electrode of the first light-emitting element is larger than a second opening of the edge cover that exposes the first electrode of the second light-emitting element, and a first light-emitting layer that overlaps the first opening and is the light-emitting layer has equal shape and equal size to a second light-emitting layer that overlaps the second opening and is the light-emitting layer.

### Advantageous Effects of Invention

According to an aspect of the present invention, a yield of a display device in which a display region is formed on a surface and a side surface can be improved.

### BRIEF DESCRIPTION OF DRAWINGS

FIG. 1(a) is a perspective view illustrating a configuration example of a display device according to a first embodiment, and FIG. 1(b) is a plan view illustrating a display panel illustrated in FIG. 1(a).

FIGS. 2(a) to 2(c) are cross-sectional views illustrating a configuration example of the display panel illustrated in FIG. 1.

FIGS. 3(a) to 3(c) are plan views illustrating a structure of a subpixel formed in the display panel illustrated in FIG. 1.

FIGS. 4(a) to 4(c) are plan views illustrating a state in which a positional offset of a light-emitting layer 24 occurs in a subpixel formed in a first side display region.

FIG. 5 is a plan view illustrating, in more detail, a configuration example of the display panel illustrated in (b) of FIG. 1.

FIG. 6 is a circuit diagram illustrating a configuration example of a subpixel formed in the display panel illustrated in FIG. 5.

FIG. 7 is a plan view illustrating an arrangement of lead wiring lines of the display panel illustrated in FIG. 5.

FIG. 8(a) is a perspective view illustrating a configuration example of a display device according to a second embodiment, and FIG. 8(b) is a plan view illustrating a display panel illustrated in FIG. 8(a).

FIG. 9 is a plan view illustrating a configuration of a first side display region according to a third embodiment.

FIG. 10 is a plan view illustrating a modified example of a subpixel formed in the first side display region.

FIG. 11 is a plan view illustrating a connection example of the subpixel illustrated in FIG. 10.

FIG. 12 is a plan view illustrating a connection example of the subpixel illustrated in FIG. 10.

FIG. 13 is a plan view illustrating another connection example of the subpixel illustrated in FIG. 10.

FIG. 14 is a plan view illustrating another connection example of the subpixel illustrated in FIG. 10.

### DESCRIPTION OF EMBODIMENTS

### First Embodiment

### Configuration Example of Display Device 1

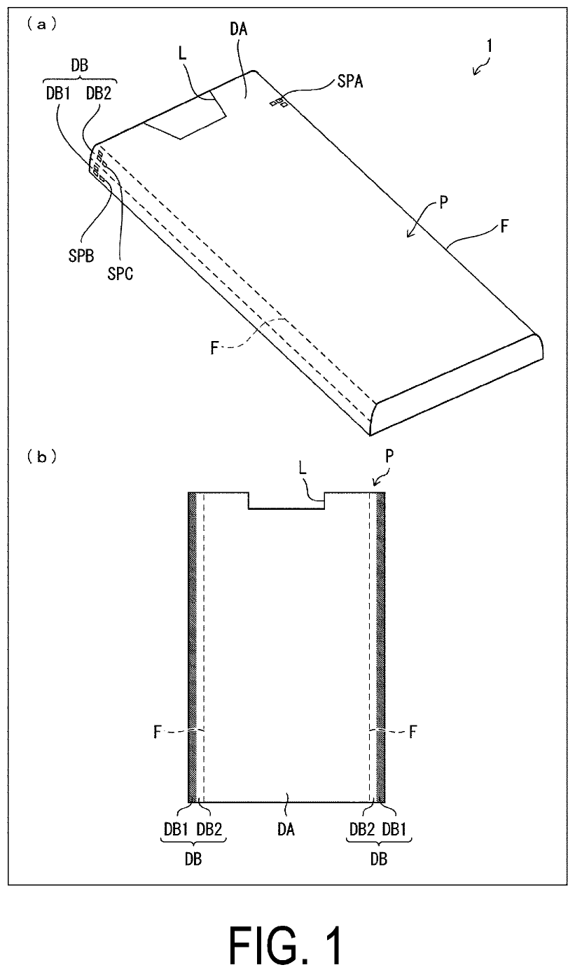

(a) of FIG. 1 is a perspective view illustrating a configuration example of a display device 1 according to a first embodiment, and (b) of FIG. 1 is a plan view illustrating a display panel P included in the display device 1 illustrated in (a) of FIG. 1. Note that (b) of FIG. 1 illustrates a flat state before the display panel P is curved along a curved line F.

The display panel P includes a surface display region DA (first display region) disposed on a surface (front) side of the display device 1, and a side display region DB (second display region) continuous with the surface display region DA and disposed on a side surface side of the display device 1. In the display device 1 according to the present embodiment, the side display region DB is formed on each of two side surfaces extending in a longitudinal direction of the display device 1. However, the side display region DB may be formed on at least one of the two side surfaces extending in the longitudinal direction of the display device 1.

Note that, in the surface display region DA of the display panel P, a notch portion L is formed in one side extending in a short-hand direction. However, the notch portion L is not necessary and may be omitted.

The side display region DB includes a first side display region DB1 and a second side display region DB2. The first side display region DB1 is formed along an end portion (both left and right end portions of the display panel P) of the side display region DB on an opposite side to the surface display region DA. The second side display region DB2 is formed so as to be sandwiched between the surface display region DA and the first side display region DB1. In other words, the second side display region DB2 is formed along an end portion of the side display region DB on the surface display region DA side.

The display panel P includes a group of subpixels SPA (first light-emitting elements) formed in the surface display region DA, a group of subpixels SPB (second light-emitting elements) formed in the first side display region DB1, and a group of subpixels SPC (third light-emitting elements) formed in the second side display region DB2. The display panel 1 displays information in the surface display region DA and the side display region DB.

Note that a shape of the display panel P is not particularly limited as long as the display panel P includes the surface display region DA and the side display region DB. For example, four corners of the display panel P may be formed at a substantially right angle or may be formed in a curved shape.

### Cross-Sectional Configuration Example of Display Panel P

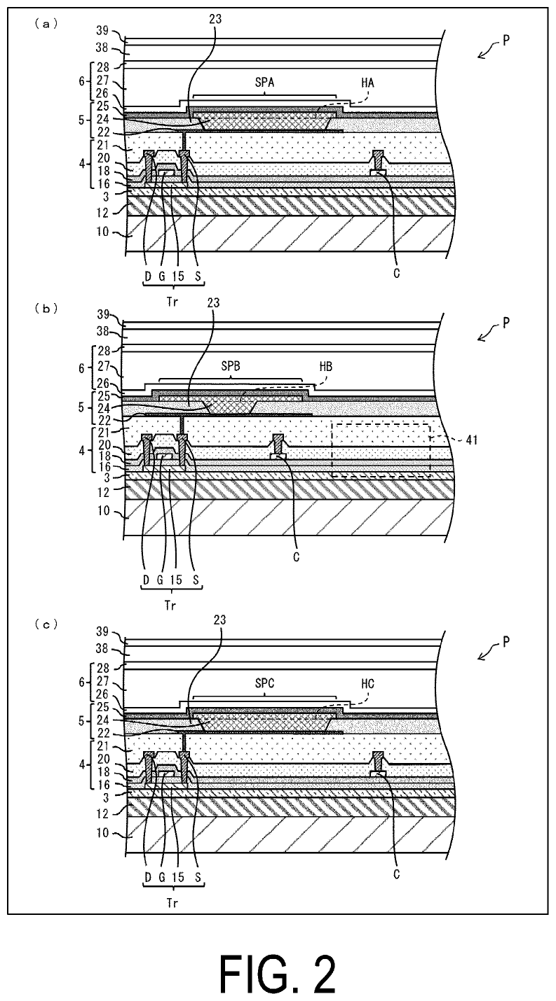

FIG. 2 is a cross-sectional view illustrating a configuration example of the display panel P according to the first embodiment. (a) of FIG. 2 illustrates an example of a cross-section of the surface display region DA, (b) of FIG. 2 illustrates an example of a cross-section of the first side display region DB1, and (c) of FIG. 2 illustrates an example of a cross-section of the second side display region DB2. The display panel P illustrated in FIG. 2 is a top-emitting device that emits light upward, and includes, in sequence from the bottom side, a base material 10, a resin layer 12, a barrier layer 3 (based layer), a TFT layer 4, a light-emitting element layer 5, a sealing layer 6, an adhesive layer 38, and a function film 39.

Examples of the material of the resin layer 12 include polyimide, epoxy, and polyamide. Examples of the material of the base material 10 include polyethylene terephthalate (PET).

The barrier layer 3 is a layer that inhibits moisture or impurities from reaching the TFT layer 4 or the light-emitting element layer 5 when the display device 1 is being used, and can be constituted by a silicon oxide film, a silicon nitride film, or a silicon oxynitride film, or by a layered film of these, for example, formed using chemical vapor deposition (CVD).

The TFT layer 4 includes a semiconductor film 15, an inorganic insulating film 16 formed in a layer above the semiconductor film 15, a gate electrode G formed in a layer above the inorganic insulating film 16, an inorganic insulating film 18 formed in a layer above the gate electrode G, a capacitance electrode C formed in a layer above the inorganic insulating film 18, an inorganic insulating film 20 formed in a layer above the capacitance electrode C, a source electrode S and a drain electrode D both formed in a layer above the inorganic insulating film 20, and a flattening film 21 formed in a layer above the source electrode S and the drain electrode D.

A thin film transistor Tr is configured to include the semiconductor film 15, the inorganic insulating film 16 (the gate insulating film), and the gate electrode G. The source electrode S is connected to a source region of the semiconductor film 15, and the drain electrode D is connected to a drain region of the semiconductor film 15.

The semiconductor film 15 is formed of low-temperature polysilicon (LTPS) or an oxide semiconductor, for example. Note that in FIG. 2, the TFT is illustrated as having a top gate structure in which the semiconductor film 15 is the channel.

Each of the inorganic insulating films 16, 18, and 20 can be formed of, for example, a silicon oxide (SiOx) film or a silicon nitride (SiNx) film, or a layered film of these, formed by using a CVD method. The flattening film (interlayer insulating film) 21 can be formed of, for example, a coatable photosensitive organic material such as a polyimide or an acrylic.

The gate electrode G, the source electrode S, the drain electrode D. and the terminals are formed of a metal single layer film or a layered film including, for example, at least one of aluminum (Al), tungsten (W), molybdenum (Mo), tantalum (Ta), chromium (Cr), titanium (Ti), and copper (Cu).

The light-emitting element layer 5 (e.g., an organic light-emitting diode layer) includes an anode electrode 22 (a first electrode) formed in a layer above the flattening film 21, an edge cover 23 that defines the subpixels SPA, SPB, or SPC in an active area (a region overlapping the light-emitting element layer 5), a light-emitting layer 24 formed in a layer above the anode electrode 22, and a cathode electrode 25 (a second electrode) formed in a layer above the light-emitting layer 24. A light-emitting element (e.g., an organic light-emitting diode, or OLED) is configured to include the anode electrode 22, the light-emitting layer 24, and the cathode electrode 25. In the display device 1, the anode electrode 22 and the cathode electrode 25 can have the opposite arrangement. In other words, the first electrode may be the cathode electrode, and the second electrode may be the anode electrode.

The edge cover 23 surrounds an end portion of the anode electrode 22. The light-emitting layer 24 is formed so as to cover a region (a light-emitting region) surrounded by the edge cover 23 by using vapor deposition or an ink-jet method. When the light-emitting element layer 5 is an organic light-emitting diode (OLED) layer, for example, a hole injection layer, a hole transport layer, the light-emitting layer 24, an electron transport layer, and an electron injection layer are layered above the bottom face of the edge cover 23 (a portion from which the anode electrode 22 is exposed). Here, the layers aside from the light-emitting layer 24 can be common layers.

The anode electrode 22 is formed by layering Indium Tin Oxide (ITO) and an alloy containing Ag, for example, and has light reflectivity (to be described below in more detail). The cathode electrode 25 can be formed of a transparent conductive material such as ITO or Indium Zinc Oxide (IZO).

If the light-emitting element layer 5 is an OLED layer, positive holes and electrons recombine inside the light-emitting layer 24 in response to a drive current between the anode electrode 22 and the cathode electrode 25, and light is emitted as a result of excitons, which are generated by the recombination, falling into a ground state. Since the cathode electrode 25 is transparent and the anode electrode 22 is photoreflective, the light emitted from the light-emitting layer 24 travels upwards and results in top emission.

The light-emitting element layer 5 is not only limited to being configured by the OLED elements, but may also be configured by inorganic light emitting diodes or quantum dot light emitting diodes.

The sealing layer 6 is transparent, and includes an inorganic sealing film 26 that covers the cathode electrode 25, the organic sealing film 27 formed in a layer above the inorganic sealing film 26, and an inorganic sealing film 28 that covers the organic sealing film 27. The inorganic sealing films 26 and 28 may be made of a silicon oxide film, a silicon nitride film, a silicon oxynitride film, or a layered film of these, formed by CVD using a mask, for example. The organic sealing film 27 is thicker than the inorganic sealing films 26 and 28, is a transparent organic film, and can be constituted with a coatable photosensitive organic material such as a polyimide or an acrylic. For example, after coating the inorganic sealing film 26 with an ink containing such an organic material using an ink-jet method, the ink is cured by UV irradiation. The sealing layer 6 covers the light-emitting element layer 5 and inhibits foreign matters, such as water and oxygen, from infiltrating to the light-emitting element layer 5.

The function film 39 has an optical compensation function, a touch sensor function, a protection function, or the like, for example.

### Structure Example of Subpixels SPA, SPB, and SPC

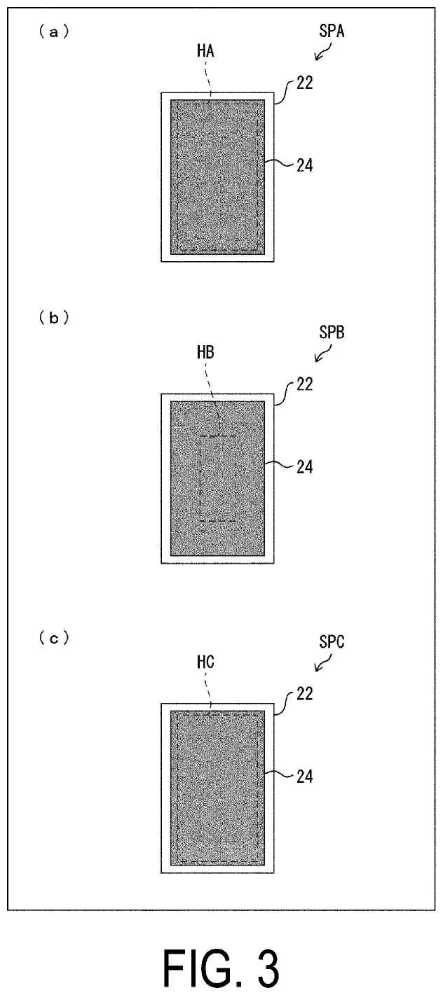

FIG. 3 is a plan view illustrating a structure example of the subpixels SPA, SPB, and SPC according to the first embodiment. As illustrated in (a) of FIG. 2 and (a) of FIG. 3, each subpixel SPA includes at least the edge cover 23 having an opening HA (a first opening), and the light-emitting layer 24 (a first light-emitting layer) disposed in a layer above the edge cover 23. In the subpixel SPA, the edge cover 23 surrounds the entire periphery of the opening HA. The light-emitting layer 24 is formed so as to completely fill at least the opening HA. The surface area of the light-emitting layer 24 is greater than the surface area of the opening HA. Of the light-emitting layer 24, a range overlapping the opening HA contributes to the information display in the surface display region DA.

As illustrated in (b) of FIG. 2 and (b) of FIG. 3, each subpixel SPB includes at least the edge cover 23 having an opening HB (a second opening), and the light-emitting layer 24 (a second light-emitting layer) that is disposed in a layer above the edge cover 23 and has equal shape and equal size to the light-emitting layer 24 in the subpixel SPA. In the subpixel SPB, the edge cover 23 surrounds the entire periphery of the opening HB. The light-emitting layer 24 is formed so as to completely fill at least the opening HB. The surface area of the light-emitting layer 24 is greater than the surface area of the opening HB. Of the light-emitting layer 24, a range overlapping the opening HB contributes to the information display in the first side display region DB1.

As illustrated in (c) of FIG. 2 and (c) of FIG. 3, each subpixel SPC includes at least the edge cover 23 having an opening HC (a third opening), and the light-emitting layer 24 (a third light-emitting layer) that is disposed in a layer above the edge cover 23 and has equal shape and equal size to the light-emitting layer 24 in the subpixel SPA and the light-emitting layer 24 in the subpixel SPB. In the subpixel SPC, the edge cover 23 surrounds the entire periphery of the opening HC. The light-emitting layer 24 is formed so as to completely fill at least the opening HC. The surface area of the light-emitting layer 24 is greater than the surface area of the opening HC. Of the light-emitting layer 24, a range overlapping the opening HC contributes to the information display in the second side display region DB2.

The “equal shape and equal size” mentioned above means that if the luminescent material of the light-emitting layer 24 is deposited in each of the surface display region DA and the side display region DB by using masks having mask patterns of equal shape and equal size, the light-emitting layers 24 of equal shape and equal size will effectively be formed in the surface display region DA and the side display region DB. Accordingly, the light-emitting layer 24 in the subpixel SPA, the light-emitting layer 24 in the subpixel SPB, and the light-emitting layer 24 in the subpixel SPC do not necessarily have to have exactly equal shape and equal size.

As illustrated in FIG. 3, the opening HA of the edge cover 23 that exposes the anode electrode 22 formed in the surface display region DA and the opening HC of the edge cover 23 that exposes the anode electrode 22 formed in the second side display region DB2 have equal shape and equal size. Further, the opening HA and the opening HC are larger than the opening HB of the edge cover 23 that exposes the anode electrode 22 formed in the first side display region DB1. Furthermore, the light-emitting layer 24 formed in the surface display region DA, the light-emitting layer 24 formed in the first side display region DB1, and the light-emitting layer 24 formed in the second side display region DB2 all have equal shape and equal size. When manufacturing the display device 1, the light-emitting layers 24 are deposited through mask openings each having equal size and formed in a fine metal mask (FMM: not illustrated) for depositing the luminescent material, in the surface display region DA, the first side display region DB1, and the second side display region DB2. In other words, the size of the mask opening formed in a range of the fine metal mask corresponding to the surface display region DA is the same as the size of the mask opening formed in a range of the fine metal mask corresponding to the first side display region DB1 and the second side display region DB2.

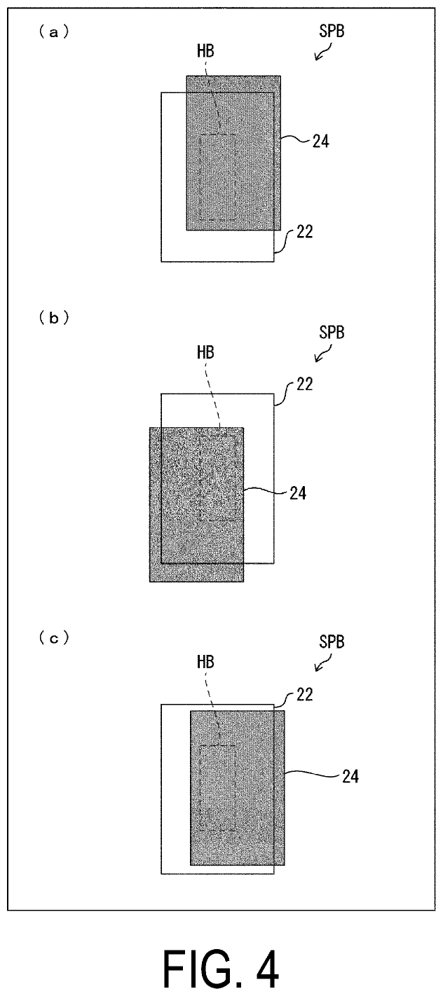

(a) to (c) of FIG. 4 are plan views illustrating a state in which a positional offset of the light-emitting layer 24 occurs in the subpixel SPB formed in the first side display region DB1. The opening HB is smaller than the opening HA and the opening HC, and thus even in a case where there is a lower mask precision in the deposition pattern used when depositing the luminescent material in the first side display region DB1, the light-emitting layer 24 is formed so as to completely cover the opening HB in the first side display region DB1. Therefore, the subpixel SPB that functions correctly can be formed in the first side display region DB1.

In this way, by making the opening HB smaller than the opening HA and the opening HC, even in a case where there is a lower mask precision in the deposition pattern used when depositing the luminescent material in the first side display region DB1, the subpixel SPB can function correctly. Specifically, when a fine metal mask is stretched while aligning with the mask opening, the fine metal mask can be stretched even in a case where a precision of the mask opening in the end portion of the fine metal mask where it is difficult to have a precision is lowered. Further, even after the fine metal mask is deposited in a mask frame, a twist is easily generated in the mask opening at the end of the fine metal mask due to a relationship in density of the mask opening of the fine metal mask. Even when the twist is generated in such a manner, the subpixel SPB can function correctly according to the present configuration. Thus, a yield of the display device 1 can be improved.

Note that, since the opening HB in the edge cover 23 formed in the second side display region DB2 is smaller than the opening HA in the edge cover 23 formed in surface the display region DA and the opening HC of the edge cover 23 formed in the second side display region DB2, the second side display region DB2 has a poorer display accuracy than the surface display region DA and the second side display region DB2. In other words, the surface display region DA and the second side display region DB2 are suited to the display of high-resolution images, whereas the first side display region DB1 is suited to the display of low-resolution images. However, the side display region DB is not located in front of the user's line of sight, and is provided mainly for icon display for starting up an application. Thus, the display quality may be changed between the surface display region DA and the side display region DB (particularly, the first side display region DB1 located at both end portions of the display panel P).

Note that the first side display region DB1 may be formed along at least the end portion (both left and right end portions of the display panel P) of the side display region DB on an opposite side to the surface display region DA. Even in this case, the yield of the display device 1 described above can be improved. However, the second side display region DB2 may be omitted, and the subpixel SPB may be formed across the entire side display region DB. In this way, the yield of the display device 1 described above can be further improved.

Note that, in order to ensure sufficient light emission from the light-emitting layer 24, a contact hole cannot be provided in the surface display region DA and the second side display region DB2 so as to overlap a part of the light-emitting layer 24 that fills the openings HA and HC. Thus, as illustrated in (a) and (c) of FIG. 2, in the surface display region DA and the second side display region DB2, a contact hole of the thin film transistor Tr is formed in a position that does not overlap the opening HA or HC. Likewise, a contact hole of the capacitance electrode C is formed in a position that does not overlap the opening HA or HC.

On the other hand, in the first side display region DB1, a part of the light-emitting layer 24 that does not overlap the opening HB does not function as the effective light-emitting layer 24. Thus, as illustrated in (b) of FIG. 2, in the first side display region DB1, the contact hole of the thin film transistor Tr can be formed in a part of the light-emitting layer 24 that does not overlap the opening HB (a part that overlaps the opening HA in the display region DA and a part that overlaps the opening HC in the second side display region DB2). Likewise, the contact hole of the capacitance electrode C can be formed in a part of the light-emitting layer 24 that does not overlap the opening HB. Thus, in the first side display region DB1, the thin film transistor Tr and the capacitance electrode C can both be provided closer to the opening HB. As a result, an empty space 41 is formed in the first side display region DB1, and an additional thin film transistor can be provided in the empty space 41. Furthermore, various types of display control circuits including the additional thin film transistor, such as a monolithic gate driver or a monolithic source driver, can be formed in the first side display region DB1. Therefore, the display device 1 including a display control circuit formed in the first side display region DB1 can be achieved.

### Arrangement Example of Display Control Circuit

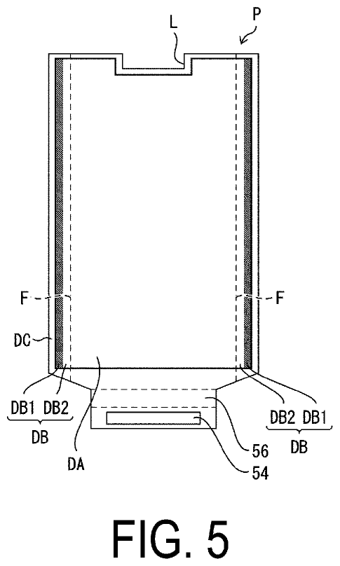

FIG. 5 is a plan view illustrating, in more detail, a configuration example of the display panel P according to the first embodiment. The display panel P illustrated in FIG. 5 includes the surface display region DA, the side display region DB, a frame region DC formed so as to surround the surface display region DA and the side display region DB, a terminal portion 54, and a bent portion 56.

Note that a pixel circuit is provided in a matrix corresponding to points in the surface display region DA and the side display region DB where the plurality of data signal lines and the plurality of scanning signal lines intersect.

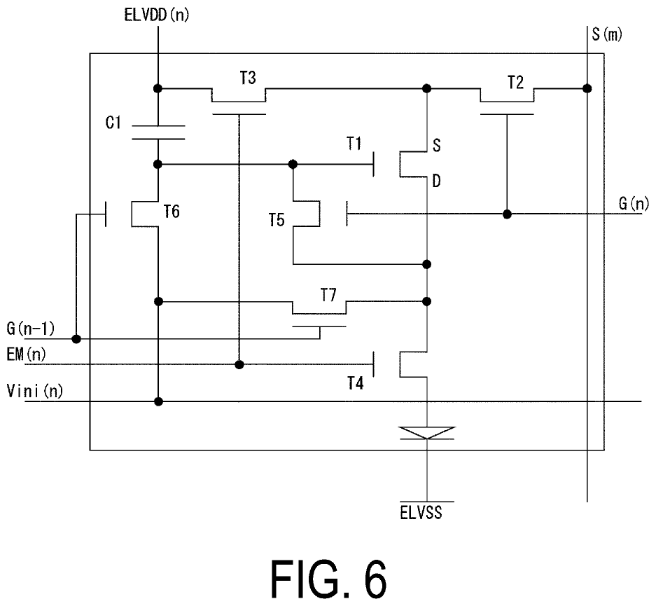

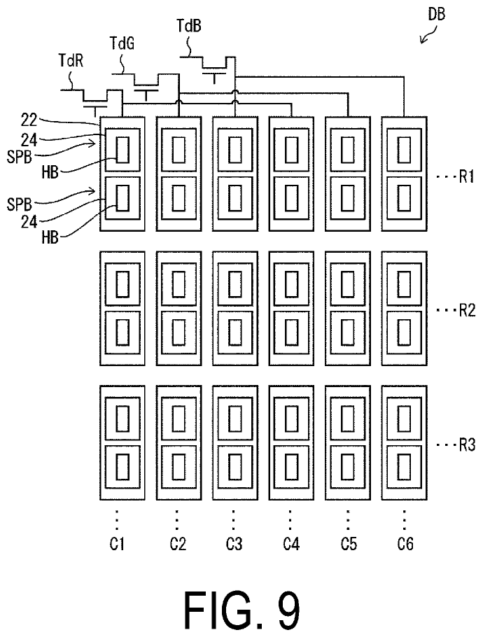

FIG. 6 is a circuit diagram illustrating a configuration example of the subpixel SPB. FIG. 9 illustrates a configuration of a pixel circuit corresponding to an mth column and an nth row. Note that the configuration of the pixel circuit described here is merely one example, and another known configuration can be employed instead.

The pixel circuit illustrated in FIG. 6 includes one organic EL element OLED, seven transistors T1 to T7 (a drive transistor T1, a writing control transistor T2, a power supply control transistor T3, a light emission control transistor T4, a threshold voltage compensation transistor T5, and initialization transistors T6 and T7), and one capacitor C1.

The transistors T1 to T7 are p-channel transistors. The capacitor C1 is a capacitance element constituted by two electrodes. A light emission control line is connected to control terminals of T3 and T4. The scanning signal line (n) is connected to control terminals of T2 and T5. The scanning signal line (n−1) is connected to control terminals of T6 and T7. However, the control terminal of T7 may be connected to the scanning signal line (n). An initialization power source line is connected to one of conduction terminals of T6 and T7. The data signal line is connected to one of conduction terminals of T2. A high power supply voltage line is connected to one of conduction terminals of T3. A cathode of the organic EL element is common in the plurality of pixel circuits and electrically connected to a low power supply voltage ELVSS.

The terminal portion 54 is formed in the frame region DC on a side of the other side on an opposite side to one side extending in the short-hand direction in which the notch portion L is formed. The terminal portion 54 is connected to the surface display region DA and the side display region DB via the bent portion 56. In such a display panel P, a display control circuit (not illustrated) such as a monolithic gate driver is formed in the first side display region DB or the frame region DC adjacent to the first side display region DB1, and the terminal portion 54 is formed in the frame region DC.

The display control circuit controls display in the surface display region DA and the side display region DB. The terminal portion 54 is attached to one end of a cable for electrically connecting the display panel P to an external device.

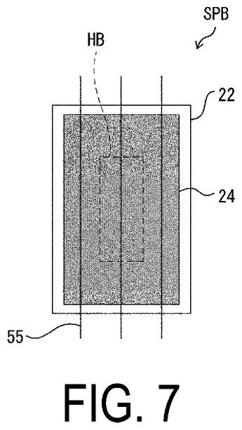

FIG. 7 is a plan view illustrating an arrangement of lead wiring lines 55. The lead wiring line 55 is a wiring line that electrically connects the surface display region DA and the side display region DB to the terminal portion 54, and transmits an external signal. As illustrated in FIG. 7, the plurality of lead wiring lines 55 are disposed so as to overlap the light-emitting layer 24 in the first side display region DB1.

### Second Embodiment

Another embodiment of the present invention will be described below. Note that, for convenience of description, members having the same functions as those of the members described in the above-described embodiment will be denoted by the same reference numerals and signs, and the description thereof will not be repeated.

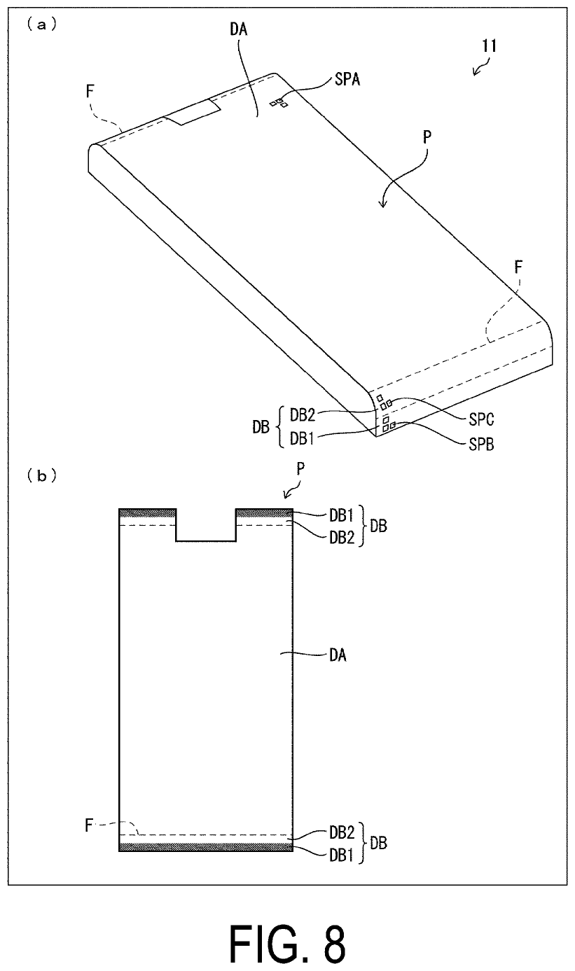

(a) of FIG. 8 is a perspective view illustrating a configuration example of a display device 11 according to a second embodiment, and (b) of FIG. 8 is a plan view illustrating a display panel P included in the display device 11 illustrated in (a) of FIG. 8. Note that (b) of FIG. 8 illustrates a flat state before the display panel P is curved along a curved line F.

The display panel P includes a surface display region DA (first display region) disposed on a surface (front) side of the display device 11, and a side display region DB (second display region) continuous with the surface display region DA and disposed on a side surface side of the display device 11. In the display device 11 according to the present embodiment, the side display region DB is formed on each of two side surfaces extending in a short-hand direction of the display device 11. However, the side display region DB may be formed on at least one of the two side surfaces extending in the short-hand direction of the display device 11.

In the surface display region DA, a notch portion L is formed in one end portion extending in the short-hand direction. However, the notch portion L is not necessary and may be omitted.

The side display region DB includes a first side display region DB1 and a second side display region DB2. The first side display region DB1 is formed along an end portion (both left and right end portions of the display panel P) of the side display region DB on an opposite side to the surface display region DA. The second side display region DB2 is formed so as to be sandwiched between the surface display region DA and the first side display region DB1. In other words, the second side display region DB2 is formed along an end portion of the side display region DB on the surface display region DA side.

The side display region DB includes a first side display region DB1 and a second side display region DB2. The first side display region DB1 is formed along an end portion (both upper and lower end portions of the display panel P) of the side display region DB on an opposite side to the surface display region DA. The second side display region DB2 is formed so as to be sandwiched between the surface display region DA and the first side display region DB1. In other words, the second side display region DB2 is formed along an end portion of the side display region DB on the surface display region DA side.

The display panel P includes a group of subpixels SPA (first light-emitting elements) formed in the surface display region DA, a group of subpixels SPB (second light-emitting elements) formed in the first side display region DB1, and a group of subpixels SPC (third light-emitting elements) formed in the second side display region DB2. The display panel 1 displays information in the surface display region DA and the side display region DB.

In this way, a position in which the side display region DB is formed is not particularly limited as long as the position is on a side surface of the display device. In other words, the side display region DB may be formed on at least one side surface of the two side surfaces extending in a longitudinal direction of the display device. Further, the side display region DB may be formed on at least one side surface of the two side surfaces extending in the short-hand direction of the display device. Furthermore, the side display region DB may be formed on both of the side surface extending in the longitudinal direction and the side surface extending in the short-hand direction of the display device.

### Third Embodiment

Another embodiment of the present invention will be described below. Note that, for convenience of description, members having the same functions as those of the members described in the above-described embodiment will be denoted by the same reference numerals and signs, and the description thereof will not be repeated.

FIG. 9 is a plan view illustrating a configuration of a side display region DB according to a third embodiment. Of all subpixels SPB arranged in the first side display region DB, FIG. 9 illustrates three rows×six columns worth of the subpixels SPB. The three rows are called rows R1, R2, and R3, in that order from the top to the bottom in FIG. 9, and the six columns are called C1, C2, . . . , C6, in that order from the left to the right in FIG. 9. In FIG. 9, the position where a given row Rn and a given column Cn intersect is called a position (Rn,Cn). For example, the position where the row R1 and the column C1 intersect is a position (R1,C1).

In FIG. 9, the plurality of subpixels SPB arranged in a first side display region DB1 include subpixels SPB that display red, subpixels SPB that display green, and subpixels SPB that display blue. The red subpixels SPB, the green subpixels SPB, and the blue subpixels SPB are arranged repeatedly, in that order, following the row direction in each row. In each position, two of the subpixels SPB that display (emit light of) the same color are arranged side-by-side following the column direction. Specifically, the two subpixels SPB arranged in the position (R1,C1) and the two subpixels SPB arranged in the position (R4,C1) are all red subpixels SPB. The two subpixels SPB arranged in the position (R2,C1) and the two subpixels SPB arranged in the position (R5,C1) are all green subpixels SPB. The two subpixels SPB arranged in the position (R3,C1) and the two subpixels SPB arranged in the position (R6,C1) are all blue subpixels SPB.

In the present embodiment, in the first side display region DB1, the plurality of subpixels SPB that display the same color can be arranged side-by-side in the column direction. In this case, the plurality of subpixels SPB arranged side-by-side in the column direction are driven by a common image signal. Furthermore, the plurality of subpixels SPB arranged side-by-side in the column direction are electrically connected to a common single anode electrode 22.

As illustrated in FIG. 9, the first side display region DB1 further includes a plurality of light emission control transistors (active elements) TdR, TdG, and TdB. The light emission control transistors TdR control the light emission of the red subpixels SPB, the light emission control transistors TdG control the light emission of the green subpixels SPB, and the light emission control transistors TdB control the light emission of the blue subpixels SPB. In FIG. 9, each of the plurality of subpixels SPB arranged in the first side display region DB1 is driven by an individual image signal corresponding to that type of display color. Specifically, the red subpixels SPB are driven by an image signal provided by the light emission control transistors TdR. The green subpixels SPB are driven by an image signal provided by the light emission control transistors TdG. The blue subpixels SPB are driven by an image signal provided by the light emission control transistors TdB.

In FIG. 9, in each position (Rn,Cn), two subpixels SPB adjacent in the column direction are electrically connected to a common anode electrode 22. The common anode electrode 22 formed in the first side display region DB1 is larger than the individual anode electrodes 22 electrically connected to subpixels SPA formed in a surface display region DA and a second side display region DB2, and is also common to two of the subpixels SPB. In the first side display region DB1, the individual anode electrodes 22 are connected to the drain electrode of any one of the light emission control transistors Td. For example, the common anode electrode 22 arranged in a position (C1,R1) is connected to the drain electrode of the light emission control transistor TdR. Accordingly, the two subpixels SPB arranged in each position (Rn,Cn) are always driven at the same time. In other words, the display device 1 cannot individually drive two subpixels SPB electrically connected to the common anode electrode 22.

In the first side display region DB1, only a single line is necessary to connect the two subpixels SPB arranged in each position (Rn,Cn) to the corresponding light emission control transistor Td. In other words, a wiring line for connecting one of the two subpixels SPB to the corresponding other light emission control transistor Td does not need to be provided in the first side display region DB1. Accordingly, the number of necessary wiring lines in the first side display region DB1 can be reduced, which can make it easier to design the subpixel structure in the first side display region DB1. Furthermore, wiring lines that connect different anode electrodes 22 to each other are not needed in the first side display region DB1, which makes it possible to freely lay out the regions in layers below the anode electrodes 22 in the first side display region DB1. In this way, a monolithic gate driver or the like, for example, can be formed in the first side display region DB1.

In the first side display region DB1, the plurality of the subpixels SPB in the group of the subpixels SPB, which are arranged in different positions, are electrically connected to a common light emission control transistor Td among the plurality of light emission control transistors TdR, TdG, and TdB. For example, the two subpixels SPB arranged in the position (R1,C1) and the two subpixels SPB arranged in the position (R4,C1) three places to the right are electrically connected to the drain electrode of a common light emission control transistor TdR. In other words, four red subpixels SPB are electrically connected to a single light emission control transistor TdR.

In FIG. 9, such a relationship “light emission control transistor Td:subpixels SPB=1:4” holds true at all locations in the first side display region DB1. For example, the two green subpixels SPB arranged in the position (R2,C1) and the two green subpixels SPB arranged in the position (R5,C1) are electrically connected to a common light emission control transistor TdG. Furthermore, the two blue subpixels SPB arranged in the position (R3,C1) and the two blue subpixels SPB arranged in the position (R6,C1) are electrically connected to a common light emission control transistor TdB.

Based on this, of all the light emission control transistors Td formed in the first side display region DB1, one quarter of those transistors are connected to any one of the subpixels SPB. The remaining three quarters do not need to be connected to subpixels SPB. As such, the locations in the first side display region DB1 where these remaining subpixels SPB are formed can be, for example, incorporated into the gate drivers or used as part of TFTs used for time-division switched driving.

### Modified Example

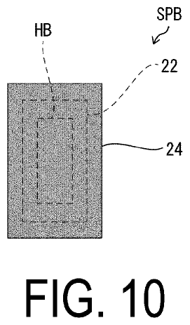

FIG. 10 is a plan view illustrating a modified example of the subpixel SPB formed in the first side display region DB1. As illustrated in FIG. 10, the dimensions of the anode electrode 22 of the subpixel SPB may be smaller than the size of the subpixel SPA formed in the surface display region DA and the subpixel SPC formed in the second side display region DB2. In this way, coupling of the anode electrode 22 of the subpixel SPB and the other wiring line can be reduced in size. Further, signal waveform rounding of the scanning signal lines and the data signal lines can be reduced.

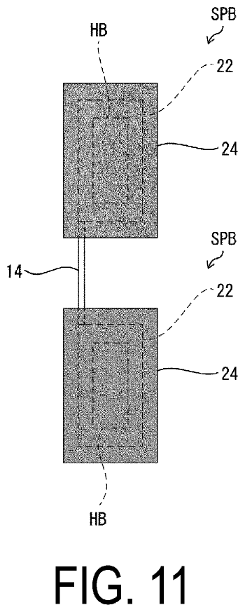

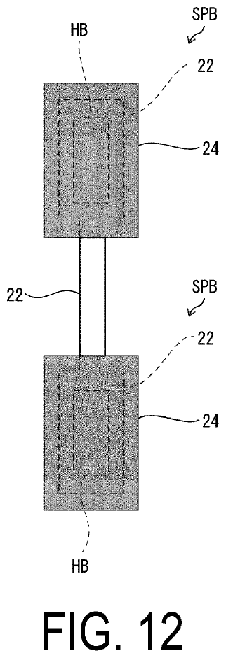

FIGS. 11 and 12 are plan views illustrating a connection example of the subpixel SPB illustrated in FIG. 10. As illustrated in FIG. 11, the anode electrodes 22 of the plurality of adjacent subpixels SPB that emit light of the same color may be electrically connected to each other via a wiring line 14 of the TFT layer 4. Further, as illustrated in FIG. 12, a common anode electrode 22 may be formed in the plurality of adjacent subpixels SPB that emit light of the same color.

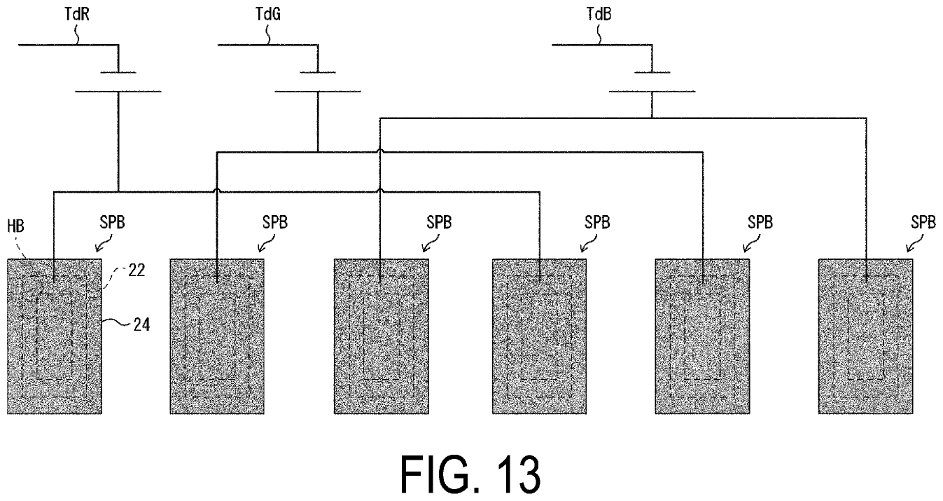

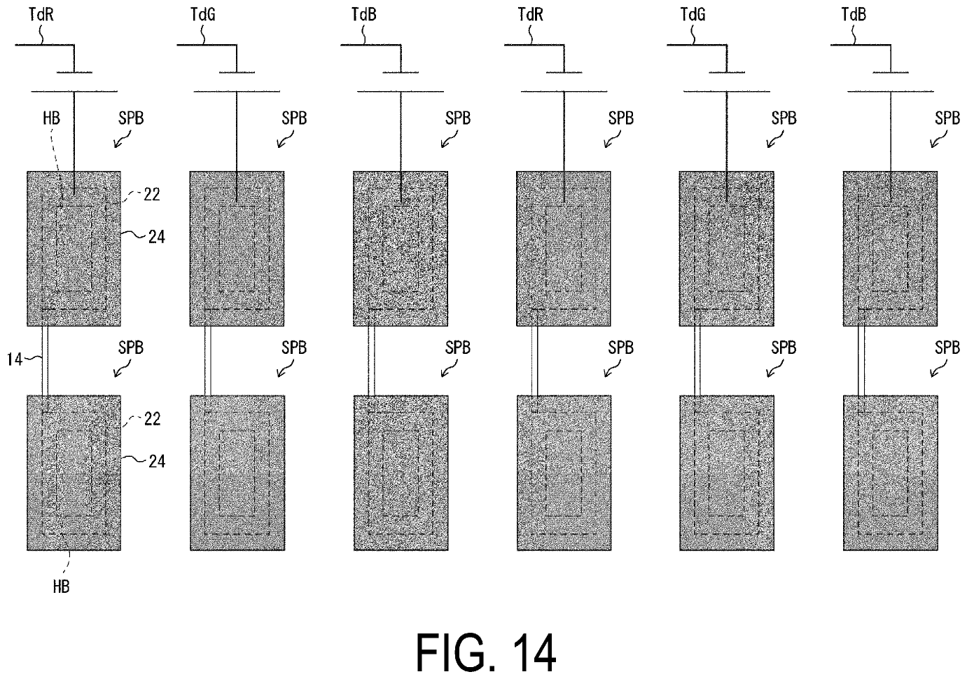

FIGS. 13 and 14 are plan views illustrating another connection example of the subpixel SPB illustrated in FIG. 10. As illustrated in FIG. 13, the plurality of subpixels SPB that emit light of the same color may be connected to common drive transistors TdR, TdG, and TdB. Further, as illustrated in FIG. 14, the plurality of adjacent subpixels SPB that emit light of the same color may be driven by a common image signal.

In all of the configurations illustrated in FIGS. 10 to 14, a pixel circuit can be reduced in size and a design space can be secured, and thus a control circuit such as a scanning signal control circuit, a light emission signal control circuit, and a source shared driving (SSD) can be formed so as to overlap the first side display region DB1.

Note that an electro-optical element (an electro-optical element of which luminance and transmittance are controlled by an electric current) included in the display device according to the first to third embodiments is not particularly limited. Examples of the display device according to the present embodiment include an organic Electro Luminescence (EL) display provided with an Organic Light Emitting Diode (OLED) as the electro-optical element, an inorganic EL display provided with an inorganic light emitting diode as the electro-optical element, and a Quantum dot Light Emitting Diode (QLED) display provided with a QLED as the electro-optical element.

### Supplement

Aspect 1: a display device in which a plurality of light-emitting elements are formed, the plurality of light-emitting elements each including a first electrode, an edge cover formed in a layer above the first electrode and covering an end portion of the first electrode, a light-emitting layer formed in a layer above the first electrode, and a second electrode formed in a layer above the light-emitting layer, the display device including: a first display region provided on a surface of the display device, a plurality of first light-emitting elements being formed in the first display region; and a second display region continuous with the first display region and provided on a side surface of the display device, a plurality of second light-emitting elements being formed in the second display region, wherein a first opening of the edge cover that exposes the first electrode of each of the plurality of first light-emitting elements is larger than a second opening of the edge cover that exposes the first electrode of each of the plurality of second light-emitting elements, and a first light-emitting layer that overlaps the first opening and is the light-emitting layer has equal shape and equal size to a second light-emitting layer that overlaps the second opening and is the light-emitting layer.

Aspect 2: the display device according to aspect 1, wherein the plurality of second light-emitting elements are formed along at least an end portion of the second display region on an opposite side to the first display region.

Aspect 3: the display device according to aspect 2, wherein, in the second display region, a third light-emitting element is formed between the plurality of first light-emitting elements and the plurality of second light-emitting elements, and the first opening has equal shape and equal size to a third opening of the edge cover that exposes the first electrode of the third light-emitting element, and the first light-emitting layer has equal shape and equal size to a third light-emitting layer that overlaps the third opening and is the light-emitting layer.

Aspect 4: the display device according to aspects 1 to 3, wherein the second display region is formed on a side surface extending in a longitudinal direction of the display device.

Aspect 5: the display device according to aspects 1 to 4, wherein the second display region is formed on a side surface extending in a short-hand direction of the display device.

Aspect 6: the display device according to aspects 1 to 5, wherein the first electrode of each of the plurality of second light-emitting elements is smaller than the first electrode of each of the plurality of first light-emitting elements.

Aspect 7: the display device according to aspects 1 to 6, wherein the first electrodes of the plurality of second light-emitting elements configured to emit light of the same color are electrically connected to each other via a wiring line of a TFT layer.

Aspect 8: the display device according to aspects 1 to 6, wherein a common first electrode is formed in the plurality of second light-emitting elements configured to emit light of the same color.

Aspect 9: the display device according to aspects 1 to 8, wherein the plurality of second light-emitting elements configured to emit light of the same color are driven by a common image signal.

Aspect 10: the display device according to aspects 1 to 8, wherein the plurality of second light-emitting elements configured to emit light of the same color are connected to a common drive transistor.

The present invention is not limited to each of the embodiments described above, and various modifications may be implemented within a range not departing from the scope of the claims. Embodiments obtained by appropriately combining technical approaches stated in each of the different embodiments also fall within the scope of the technology of the present invention. Novel technical features may also be formed by combining the technical approaches stated in each of the embodiments.

### REFERENCE SIGNS LIST

1 Display device
DA Surface display region (first display region)
DB Side display region (second display region)
DB1 First side display region (second display region)
DB2 Second side display region (second display region)
DC Frame region
SPA Subpixel (first light-emitting element)
SPB Subpixel (second light-emitting element)
SPC Subpixel (third light-emitting element)
14 Wiring line of TFT layer
22 Anode electrode (first electrode)
23 Edge cover
25 Cathode electrode (second electrode)
HA Opening (first opening)
HB Opening (second opening)
HC Opening (third opening)
24 Light-emitting layer (first light-emitting layer, second light-emitting layer, and third
light-emitting layer)
TdR Light emission control transistor (drive element)
TdB Light emission control transistor (drive element)
TdG Light emission control transistor (drive element)

1. A display device in which a plurality of light-emitting elements are formed, the plurality of light-emitting elements each including a first electrode, an edge cover formed in a layer above the first electrode and covering an end portion of the first electrode, a light-emitting layer formed in a layer above the first electrode, and a second electrode formed in a layer above the light-emitting layer, the display device comprising:
a first display region provided on a surface of the display device, a plurality of first light-emitting elements being formed in the first display region; and
a second display region continuous with the first display region and provided on a side surface of the display device, a plurality of second light-emitting elements being formed in the second display region,
wherein a first opening of the edge cover that exposes the first electrode of the first light-emitting element is larger than a second opening of the edge cover that exposes the first electrode of the second light-emitting element, and
a first light-emitting layer that overlaps the first opening and is the light-emitting layer has equal shape and equal size to a second light-emitting layer that overlaps the second opening and is the light-emitting layer.

2. The display device according to claim 1,
wherein the second light-emitting element is formed along at least an end portion of the second display region on an opposite side to the first display region.

3. The display device according to claim 2,
wherein, in the second display region, a third light-emitting element is formed between the plurality of first light-emitting elements and the plurality of second light-emitting elements, and the first opening has equal shape and equal size to a third opening of the edge cover that exposes the first electrode of the third light-emitting element, and
the first light-emitting layer has equal shape and equal size to a third light-emitting layer that overlaps the third opening and is the light-emitting layer.

4. The display device according to claim 1,
wherein the second display region is formed on a side surface extending in a longitudinal direction of the display device.

5. The display device according to claim 1,
wherein the second display region is formed on a side surface extending in a short-hand direction of the display device.

6. The display device according to claim 1,
wherein the first electrode of each of the plurality of second light-emitting elements is smaller than the first electrode of each of the plurality of first light-emitting elements.

7. The display device according to claim 1,
wherein the first electrodes of the plurality of second light-emitting elements configured to emit light of the same color are electrically connected to each other via a wiring line of a TFT layer.

8. The display device according to claim 1,
wherein a common first electrode is formed in the plurality of second light-emitting elements configured to emit light of the same color.

9. The display device according to claim 1,
wherein the plurality of second light-emitting elements configured to emit light of the same color are driven by a common image signal.

10. The display device according to claim 1,
wherein the plurality of second light-emitting elements configured to emit light of the same color are connected to a common drive transistor.
